(19) United States
(12) Patent Application Publication
(10) Pub. No.: US 2024/0363502 A1
(43) Pub. Date: Oct. 31, 2024

(54) SEMICONDUCTOR DEVICE

(71) Applicant: Infineon Technlolgies AG, Neubiberg (DE)

(72) Inventors: Stefan Beyer, Villach (AT); Jia Yi Wong, Unterhaching (DE); Marius Aurel Bodea, Villach (AT)

(21) Appl. No.: 18/636,429

(22) Filed: Apr. 16, 2024

(30) Foreign Application Priority Data
Apr. 26, 2023 (DE) 102023203869.2

(51) Int. Cl. H01L 23/495

(52) U.S. Cl. CPC H01L 23/49562; H01L 23/49548

(57) ABSTRACT

A semiconductor device is provided. The semiconductor device may include a semiconductor substrate including an active area, and a metal layer structure over the active area. The metal layer structure is configured to form an electrical contact. The metal layer structure includes a solder area, a buffer area, and a barrier area between the solder area and the buffer area. In the barrier area, the metal layer structure is arranged over a barrier base structure. The barrier base structure includes at least two segments extending along two different directions and a curved connecting segment connecting the at least two segments.

### TECHNICAL FIELD

Various embodiments relate generally to a semiconductor device.

### BACKGROUND

Using copper (Cu) clips in transistor outline (TO) packages is a fairly recent development, wherein a soft solder, a diffusion solder or a solder paste is used for clip attach. During the clip attach, a solder coverage (under the clip) is a critical process, which is controlled to ensure that more than approximately 80% under the clip is covered by solder.

This is important to obtain a low R_{DS(on)}, a high power efficiency, and a good interconnect from the source pad to a lead frame.

However, it is challenging to control the solder bleed out and at the same time ensure the good solder coverage under the clip. Excessive solder bleed out may contaminate the bond pad, which may lead to a short in a case where the bled-out solder reaches additional bond pads (contacts) and may result in nonstick-on-pad during wire bonding.

DE 10 2018 124 497 B4 describes a basic concept of a semiconductor device having a barrier area (also referred to as a confinement structure) between a solder area and a buffer area, wherein, in the barrier area, a metal layer structure extends further away from an active area of the semiconductor device than in adjacent areas.

### SUMMARY

A semiconductor device is provided. The semiconductor device may include a semiconductor substrate including an active area, a metal layer structure over the active area, wherein the metal layer structure is configured to form an electrical contact, the metal layer structure including: a solder area, a buffer area, and a barrier area between the solder area and the buffer area, wherein, in the barrier area, the metal layer structure is arranged over a barrier base structure, and wherein the barrier base structure includes at least two segments extending along two different directions and a curved connecting segment connecting the two segments.

The semiconductor device may include a semiconductor substrate including an active area, a metal layer structure over the active area, wherein the metal layer structure is configured to form an electrical contact, the metal layer structure including: a solder area, a buffer area, a barrier area between the solder area and the buffer area, and an insulated metal structure extending from an edge region of the semiconductor device to the solder area, wherein, in the barrier area, the metal layer structure is arranged over a barrier base structure, and wherein the barrier base structure is formed as a contiguous structure that surrounds the solder area, except for gaps in the barrier base structure through which the insulated metal structure extends.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B each show a schematic top view and a partial zoomed-in view of a semiconductor device in accordance with various embodiments;

FIGS. 1C and 1D each show a schematic top partial zoomed-in view of a semiconductor device in accordance with various embodiments;

FIG. 2 shows a schematic cross-sectional view of a semiconductor device in accordance with various embodiments;

FIGS. 3A to 3C each show a schematic top view and a partial zoomed-in view of a semiconductor device in accordance with various embodiments;

FIG. 4 shows a schematic top view of and two partial zoomed-in views of a semiconductor device in accordance with various embodiments;

FIG. 5 shows a flow diagram of a method of forming a semiconductor device in accordance with various embodiments; and

FIG. 6 shows a flow diagram of a method of forming a semiconductor device in accordance with various embodiments.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

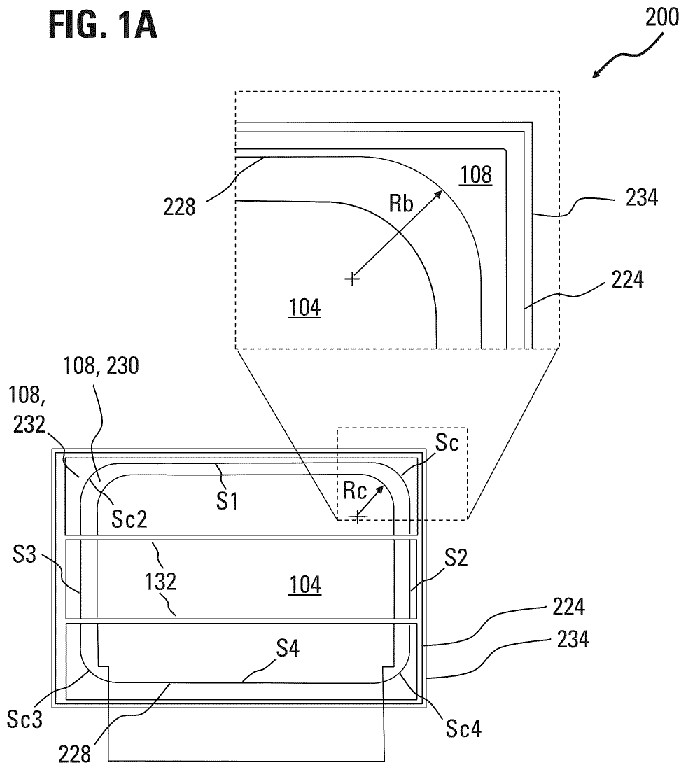

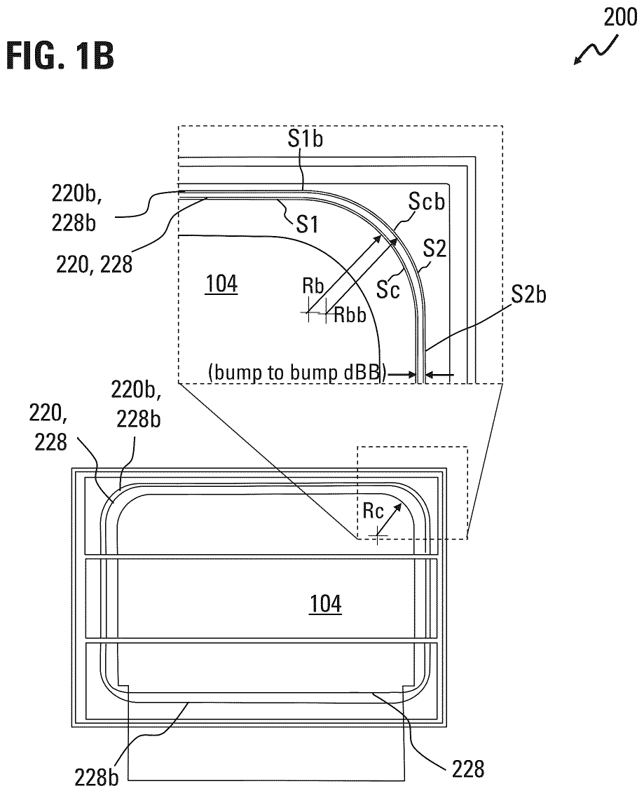

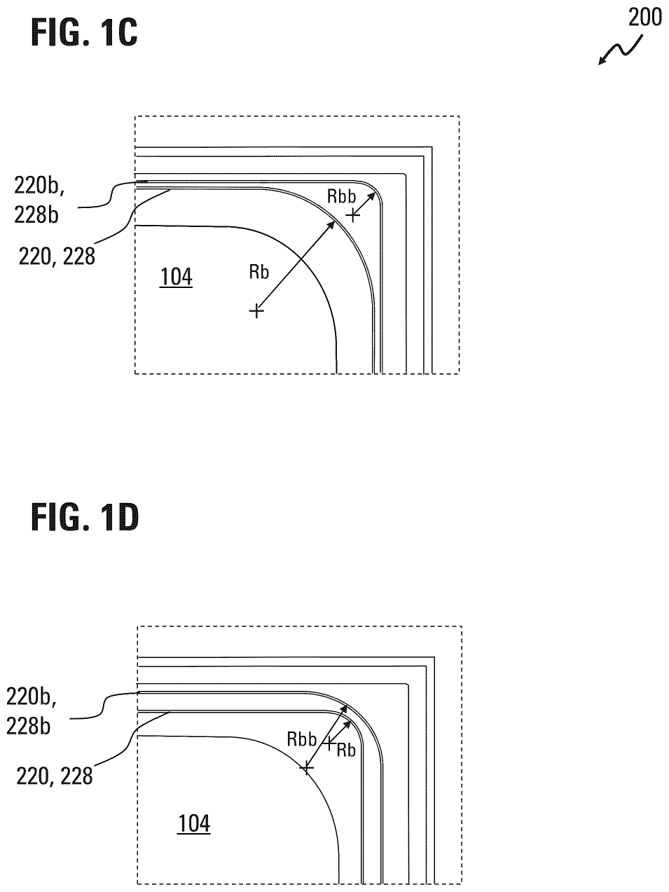

FIGS. 1A and 1B each show a schematic top view and a partial zoomed-in view of a semiconductor device in accordance with various embodiments, and FIGS. 1C and 1D each show a schematic top partial zoomed-in view of a semiconductor device in accordance with various embodiments.

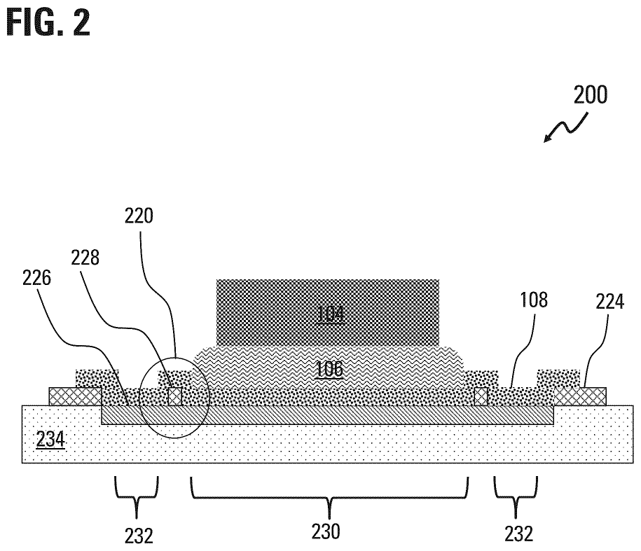

The semiconductor device 200 may in various embodiments include a metal layer structure 108 formed over a semiconductor substrate 234. The semiconductor device 200 may include an active area 226 of the semiconductor device 200 (the active area 226 is indicated in FIG. 2).

The active area 226 may be covered by the metal layer structure 108. The metal layer structure 108 may be a single metal layer 108 or a metal layer stack 108 including a plurality of metal layers. The metal of the metal layer structure 108 may include or consist of any metal or combination of metals typically used for forming an electrical contact and suitable for the semiconductor device 200, for example copper, a copper alloy, a copper-chromium alloy, gold, aluminum, nickel, a nickel alloy, titanium, a titanium alloy, tungsten, a tungsten alloy, and/or a titanium-tungsten alloy. The metal layer structure 108 may have a thickness in a range from about 100 nm to about 100 μm, e.g. in a range from about 1 μm to about 10 μm, e.g. about 5 μm.

The metal layer structure 108 may be formed as known in the art, e.g. by a deposition process, e.g. a vapor deposition process, a plating process, or the like. Masks, e.g. using a photolithographic masking process, may be used for a structuring of the metal layer structure 108.

The semiconductor device 200 may for example form a discrete electronic component, e.g. a diode, a thyristor, a MOSFET, a superjunction transistor, and an IGBT. The semiconductor device 200 may for example form a power electronic component. The semiconductor device 200 may be configured to have a current flow in a vertical direction through the semiconductor device 200.

The metal layer structure 108 may be configured to form an electrical contact (e.g. a source contact) of the semiconductor device 200.

The metal layer structure 108 may include a solder area 230, a buffer area 232, and a barrier area 220 between the solder area 230 and the buffer area 232. These areas may be more easily identified in FIG. 2.

The solder area 230, the buffer area 232 and the barrier area 220 may be formed as one continuous metal layer structure 108 and may be differentiated by their relative positions, their shapes, and/or by their functionality, as described in the following.

Each of the solder area 230 and the buffer area 232 may be in direct contact with the active area 226. In other words, the metal layer structure 108 may be arranged to cover the active area 226, such that an electrical contact to the active area 226 provided by the metal layer structure 108 extends over the whole area of the active area 226 in order to ensure a high efficiency.

In the barrier area 220, the metal layer structure 108 may be further away from the active area 226 than in the solder area 230 and in the buffer area 232. In the barrier area 220, the metal layer structure 108 may be arranged over a barrier base structure 228. In other words, the barrier base structure 228 may be formed over the semiconductor substrate 234, e.g. on the active area 226 or on the wiring layer 236, and the metal layer structure 108 may be formed over it (and the remaining portions of the active area 226 or the wiring layer 236, respectively).

The barrier base structure 228 includes at least two segments S1, S2 extending along two different directions and a curved connecting segment Sc connecting the two segments S1, S2.

The barrier base structure 228 may be a single barrier base layer or a barrier base layer stack including a plurality of barrier base layers. The barrier base structure 228 may be formed as known in the art, e.g. by a deposition process, e.g. a vapor deposition process, a plating process or the like. Masks, e.g. using a photolithographic masking process, may be used for a structuring of the barrier base structure 228.

In various embodiments, the barrier base structure 228 may include or consist of a dielectric material, e.g. an imide, an oxide, and/or a nitride. This may be advantageous in a case that the semiconductor device 200 includes a passivation layer 224 over, e.g. on, the semiconductor substrate 234 outside the active area 226 and/or an insulated metal structure 132. In that case, a material of the passivation layer 224 and/or the insulating material of the insulated metal structure 132 may be selected to be the same as the dielectric material of the barrier base structure 228 (or vice versa), which means that the passivation layer 224 and the barrier base structure 228 may be formed simultaneously.

In various embodiments, the barrier base structure 228 may include or consist of a metal, for example any, some, or all of aluminum, tungsten, copper, and alloys thereof. Thereby, a direct electrically conductive contact may also be provided between the barrier area 220 and the active area 226. The metal of the barrier base structure 228 may in various embodiments be the same as the metal of the metal layer structure 220. In a case of the metal layer structure 220 forming the layer stack, the metal of the barrier base structure 228 may be the same as the layer of the metal layer structure 220 directly contacting the barrier base structure 228.

In various embodiments, the barrier base structure 228 may include a mixture of one or more metal layer(s) and one or more dielectric layer(s).

A height of the barrier base structure 228 may in various embodiments be in a range from about 3 μm to about 100 μm, e.g. from about 10 μm to about 50 μm, e.g. about 25 μm. A width of the barrier base structure 228 may be in a range from about 2 μm to about 25 μm, e.g. from about 5 μm to about 20 μm, e.g. about 13 μm. In various embodiments, the width of the barrier base structure 228 may be larger than its height. The width of the barrier base structure 228 may be determined by technological limitations, e.g. of a lithography process. For example, using an imide for the barrier base structure 228, a width of 10 μm may be achieved for the barrier base structure 228 having a thickness of 6 μm.

In various embodiments, the solder area 230 may be configured to be contacted by a metal contact structure 140 (e.g., a clip, for example as shown in FIG. 1A and FIG. 1B) with a rounded corner. A radius of curvature Rc of the rounded corner of the metal contact structure 140 may for example be 500 μm or more, for example between 500 μm and about 1 mm.

The rounded corner may be configured to be arranged adjacent to the curved connecting segment Sc, and may have the predefined radius of curvature Rc. A radius of curvature Rb of the curved connecting segment Sc may be in a range from 50% to 200%, optionally 100%, of the predefined radius of curvature Rc. Optionally, which is shown in FIG. 1B, the radii of curvature of the metal contact structure 140 and of the curved segment Sc of the barrier area 220 may be the same or about the same.

A radius of curvature Rb of the curved connecting segment may in various embodiments be in a range from about 10 μm to about 1 mm. FIG. 1B shows an embodiment in which the radius of curvature Rb is about 500 μm and matches the radius of curvature Rc of the metal contact structure 104.

The segments S1, S2 of the barrier area 220 (and thus, corresponding segments of the barrier base structure 228) may extend parallel to edges of the semiconductor substrate 234. The two different directions in which the segments S1, S2 extend may be orthogonal to each other.

In various embodiments, the semiconductor device 200 may include a further barrier area 220b between the barrier area 220 and the buffer area 232, wherein the further barrier area 220b may be formed to encircle the barrier area 220 at least partly, optionally fully or almost fully. The further barrier area 220b may in principle be formed in the same way (and, optionally, during the same process, thus further optionally using the same materials) as the barrier area 220, thus respective descriptions are omitted.

In the further barrier area 220b, the metal layer structure 108 may be arranged over a further barrier base structure 228b. The further barrier area 220b, and thus the further barrier base structure 228b, may include at least two segments S1b, S2b extending along two different directions and a curved connecting segment Scb connecting the two segments S1b, S2b.

Optionally, the barrier area 220 and the further barrier area 220b may be parallel. An exemplary embodiment of such a configuration is shown in FIG. 1B.

Optionally, a radius of curvature Rbb of the curved connecting segment Scb of the further barrier base area 220b (the further barrier base structure 228b) may be larger (see FIG. 1D) or smaller (see FIG. 1C) than the radius of curvature Rb of the curved connecting segment of the barrier area 220 or, respectively, the barrier base structure 228.

Further optionally, the radius of curvature Rbb of the curved connecting segment Scb of the further barrier base area 220b (the further barrier base structure 228b) may the same as the radius of curvature Rb of the curved connecting segment of the barrier area 220 or, respectively, the barrier base structure 228.

In various embodiments, the semiconductor device 200 may further include one or more additional segments S3, S4 and additional curved segments Sc2, Sc3, Sc4 connecting the segments S1, S2 with the additional segments S3, S4 and/or the additional segments S3, S4 with each other. To avoid crowding in the figures, the additional segments S3, S4 and additional curved segments Sc2, Sc3, Sc4 are indicated only in FIG. 1A. The curved segment Sc1 and the additional curved segments Sc2, Sc3, Sc4 may have the same radius of curvature Rb (a corresponding exemplary embodiment is shown in FIG. 1A), or may have different radii of curvature Rb (a corresponding exemplary embodiment is shown in FIG. 1B, where the radius of curvature Rb of the curved segment Sc1 is the same as the radius of curvature Rb of the additional curved segment Sc2, but both are different from those of the additional curved segments Sc3 and Sc4).

Even though the curved segments Sc are shown as portions of a circle (with a defined radius), they may have any curved shape that avoids connecting the segments S1, S2 (, S3, S4, . . . ) with a sharp feature (e.g., corner, chamfer). For example, a parabolic shape or any other smooth curved function may be used as the curved segment Sc.

In various embodiments, the barrier area 220 in the semiconductor device 200 is formed without sharp corners, chamfers. In various embodiments, also blunt edges may be avoided.

By providing the curved segments Sc, in various embodiments, a solder 106 coverage under the metal connection structure 104 may be optimized to ensure low product R_{DS(on)} and a high power efficiency. This will help to prevent a reliability issue of a lifted wire-on-pad during or after the metal connection structure 104 attach due to a bond pad contamination by the solder 106.

Without sharp corners, relatively high peak forces on the solder in the corners during a clip attach, and thus an overflow during clip attach at the corner in the barrier area 220 design, may be avoided. In addition, resist issues during a Cu lithography process, and/or holes in the Cu layer that may result from resist issues, may be avoided.

To summarize, solder spilling at corners and/or defective resist coverage may be avoided or at least mitigated.

The encircling barrier area 220 (barrier base structure 228) may be ring-shaped in the sense that it forms a structure that is closed upon itself. Optionally, the ring shape may have interruptions, in particular in a case where the semiconductor device 200 is combined with features of the semiconductor device 400.

The reduced or avoided contamination of the buffer area 232 and/or of the further contact(s) 112 may improve a quality of contact between bond wires and further contact(s), and also improve an adhesion of packaging material to the buffer area, and avoid or alleviate a dendrite growth outside the solder area 230.

A distance between the barrier area 220 and the further barrier area 220b (and, correspondingly, between the barrier base structure 228 and the further barrier base structure 228b) may be in a range from about 20 μm to about 100 μm, e.g. about 30 μm (the 30 μm bump to bump dBB is indicated in FIG. 1B)

In various embodiments, more than two barrier areas may be provided, e.g. three or more barrier areas.

The zoomed image in FIG. 2 shows a cross-sectional view of the barrier area 220 (copper) with the barrier base structure 228 (e.g., imide) underneath the metal layer structure 108. The barrier area 220 separates the solder area 230 from the buffer area 232.

Below the barrier base structure 228 and the metal layer structure 108, an active area 226 is shown as part of the semiconductor substrate 234.

As described above, the semiconductor device 200 may include the metal contact structure 104, e.g. a metal clip, having a solder portion soldered (by solder 106) to the solder area 230 of the metal layer structure 108. The solder 106 may be a solder metal or a solder metal paste. By way of example, the solder 106 may be lead free or may include lead. The solder 106 may include or essentially consist of one or more of the following materials: SnAg and/or Pb and/or SnAgSb.

The metal contact structure 104 may have a width in a range from about 1 mm to about 2 mm, a height in a range from about 3 mm to about 5 mm, and curved corners having a radius of curvature Rc, wherein Rc may be larger than about 500 μm.

In various embodiments, lateral dimensions of the solder area 230 may be configured to be at least slightly larger than lateral dimensions of the solder portion. For example, a width and a length of an area encircled by the inner barrier base structure 228, which essentially (except for the metal layer structure 108 to be arranged over the barrier base structure 228) corresponds in dimensions to the solder area 230, may be just slightly larger (e.g. by about 5% to about 10% in each dimension) than the solder portion of the metal contact structure 104. In other words, the barrier area 220 may be formed laterally outside the metal contact structure 104, e.g. the clip.

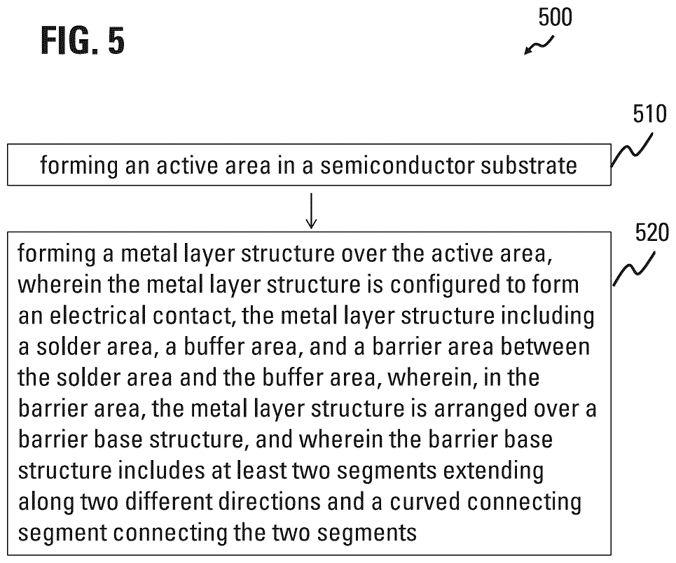

FIG. 5 shows a flow diagram 500 of a method of forming a semiconductor device in accordance with various embodiments.

The method may include forming an active area in a semiconductor substrate (in 510) and forming a metal layer structure over the active area, wherein the metal layer structure is configured to form an electrical contact, the metal layer structure including a solder area, a buffer area, and a barrier area between the solder area and the buffer area, wherein, in the barrier area, the metal layer structure is arranged over a barrier base structure, and wherein the barrier base structure includes at least two segments extending along two different directions and a curved connecting segment connecting the two segments (in 520).

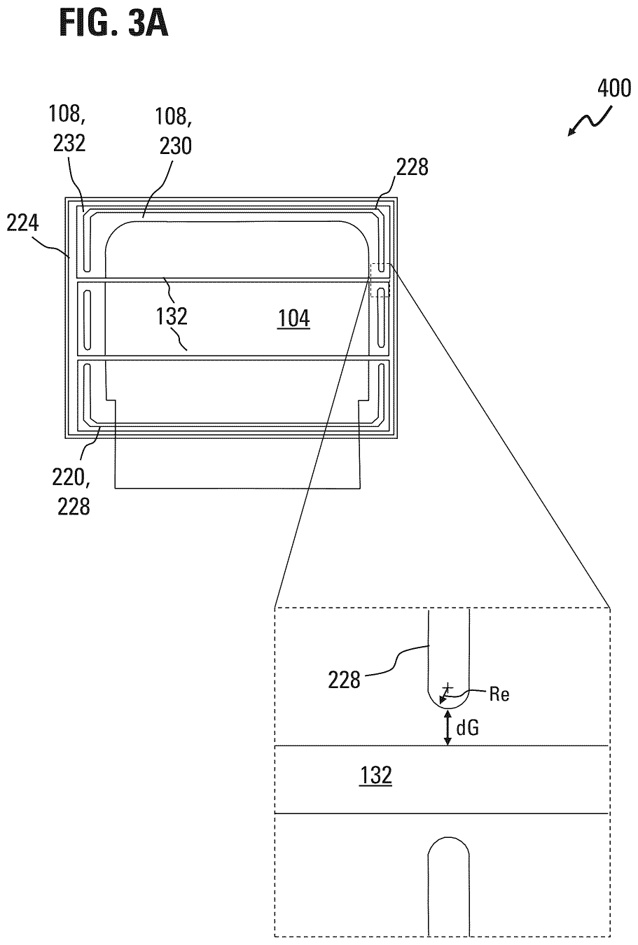

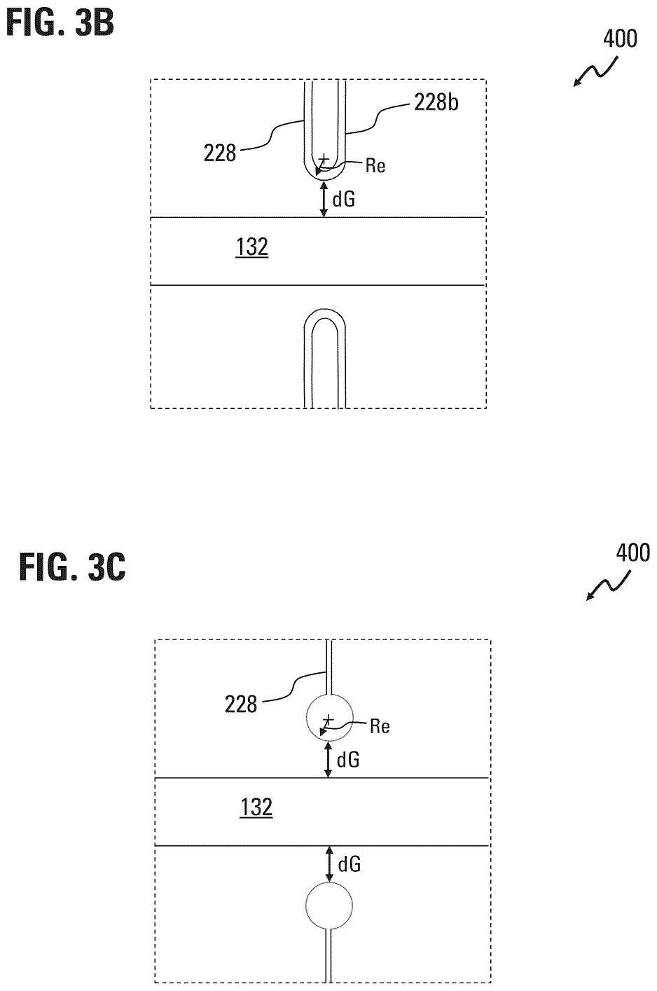

FIG. 3A shows a schematic top view with a top zoomed-in view of a semiconductor device 400 in accordance with various embodiments, and each of FIGS. 3B and 3C shows a schematic top zoomed-in view of a semiconductor device 400 in accordance with various embodiments.

The semiconductor device 400 may in various embodiments include features that are similar or identical to those of the semiconductor device 200 as described above. For example, the semiconductor device 400 may include a metal layer structure 108 formed over a semiconductor substrate 234. The semiconductor device 400 may include an active area 226 of the semiconductor device 400 (the active area 226 is indicated in FIG. 2). The metal layer structure 108 may include a solder area 230, a buffer area 232, and a barrier area 220 between the solder area 230 and the buffer area 232. These areas may be more easily identified in FIG. 2.

The semiconductor device 400 may in various embodiments further include an insulated metal structure 132 extending from an edge region of the semiconductor device 400 to the solder area 230.

In the barrier area 220, the metal layer structure 108 may be arranged over a barrier base structure 228. The barrier base structure 228 may be formed as a contiguous structure that surrounds the solder area, except for gaps in the barrier base structure 228 through which the insulated metal structure 132 extends.

By avoiding a connection between the barrier base structure 228 and the insulated metal structure 132, it is avoided that moisture creeps along the barrier base structure 228 towards the solder area 230 and causes delamination in that area. Instead, moisture is limited to the (more or less immediate) vicinity of the insulated metal structure 132.

The insulated metal structure 132 may for example be a gate finger or a sensor connection, for example for sensing current and/or voltage. Optionally, the insulated metal structure 132 may extend from the edge region of the semiconductor device 400 to an opposite edge region of the semiconductor device 400.

A distance dG between the insulated metal structure 132 and the barrier base structure 228 may be in a range from about 5 μm to about 100 μm, for example about 30 μm.

In various embodiments, a terminal portion of the barrier base structure 228 adjacent to the insulated metal structure 132 may be rounded, curved or circular.

In other words, also at a terminal portion of the barrier base structure 228, sharp corners/edges may be avoided.

FIGS. 3A to 3C show various exemplary embodiments of how the rounded terminal portion of the barrier area 220 (e.g., of the barrier base structure 228) may be configured.

In FIG. 3A, the terminal portion of a moderately broad barrier base structure 228 may be provided as a rounded (e.g., semi-circular) terminal portion. A radius of curvature Re of the terminal portion may correspond to a half width of the barrier base structure 228, for example in a range from about 10 μm to about 50 μm.

In FIG. 3B, the terminal portion may be provided as a curved connection between the barrier base structure 228 and a further barrier base structure 228b (the further barrier base structure 228b may for example be configured as described above). A radius of curvature of the curved connection may for example be about a half-distance between the barrier base structure 228 and the further barrier base structure 228b, e.g. about 30 μm, or different from that value.

In FIG. 3C, the terminal portion of a relatively narrow barrier base structure 228 may be provided as a circular terminal portion that is attached to the barrier base structure 228. A radius of curvature Re of the terminal portion may or example be in a range from about 10 μm to about 50 μm.

The insulated metal structure 132 of the semiconductor device 400 may be formed from a metal structure that extends from an edge region of the semiconductor device 400 to the active area 226 of the semiconductor device 400 and may be covered by an insulating material. In various embodiments, in the semiconductor device 400, the barrier area 220 and the insulated metal structure 132 may be disconnected. In other words, the barrier area may be interrupted (opened) to allow the insulated metal structure 132 to pass through without making contact. A minimum distance dG between the insulated metal structure 132 and an end of the barrier area 220 may in various embodiments be 30 μm or more.

The disconnection/separation between the barrier area 220 and the insulated metal structure 132 may prevent or at least mitigate a moisture uptake through the insulated metal structure 132 and further along the barrier structure into the solder area 230.

As a consequence, a reliability of the semiconductor device is increased, because no or only very little moisture that could cause delamination can enter the insulated metal structure 132 and propagate along the barrier structure.

Furthermore, in various embodiments, ends of the barrier area 220 may be formed without sharp corners, blunt edges or chamfers. Ends of the barrier area 220 may in various embodiments be formed with curved or rounded ends or edges, for example by providing a single barrier base structure 228 with a rounded end, or by connecting a barrier base structure 228 and a further barrier base structure 228b by a curved connection.

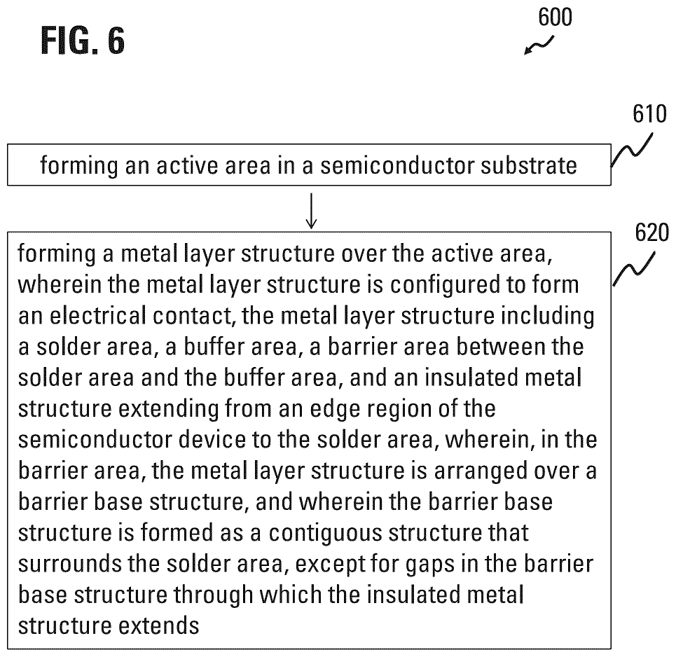

FIG. 6 shows a flow diagram 600 of a method of forming a semiconductor device in accordance with various embodiments.

The method may include forming an active area in a semiconductor substrate (in 610) and forming a metal layer structure over the active area, wherein the metal layer structure is configured to form an electrical contact, the metal layer structure including a solder area, a buffer area, and a barrier area between the solder area and the buffer area, and an insulated metal structure extending from an edge region of the semiconductor device to the solder area, wherein, in the barrier area, the metal layer structure is arranged over a barrier base structure, and wherein the barrier base structure is formed as a contiguous structure that surrounds the solder area, except for gaps in the barrier base structure through which the insulated metal structure extends (in 620).

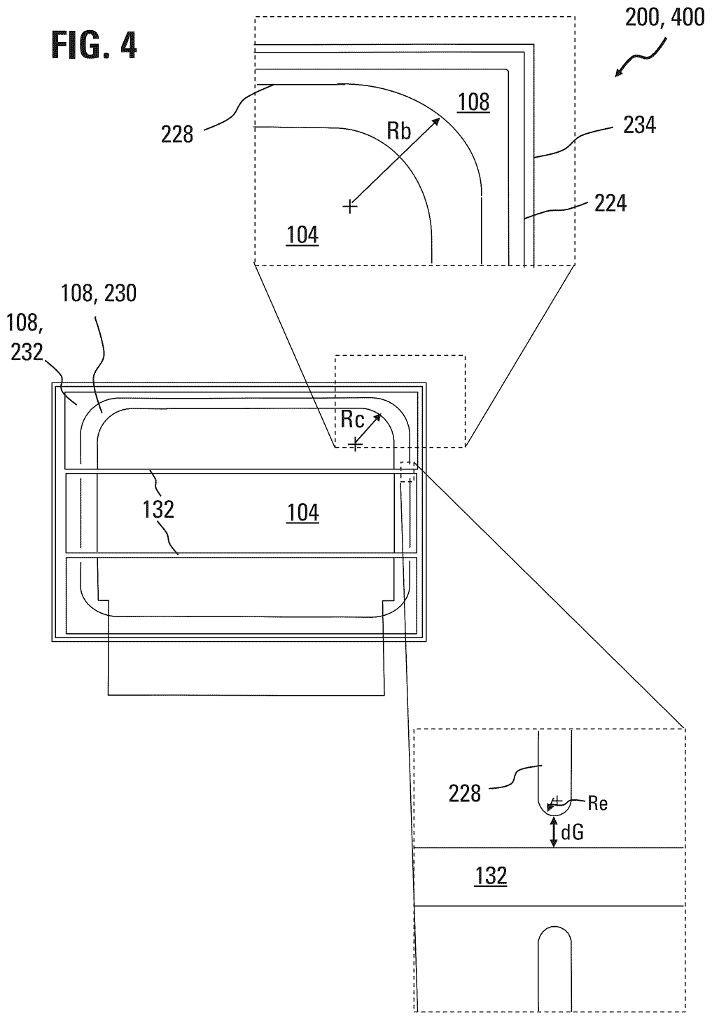

FIG. 4 shows a schematic top view of and two partial zoomed-in views of a semiconductor device 200, 400 in accordance with various embodiments.

Features of the semiconductor device 200 and of the semiconductor device 400 may be combined into a single semiconductor device. FIG. 4 shows just an exemplary embodiment thereof. Any of the features described in context with the semiconductor device 200 may be combined with any other features of the semiconductor device 400.

In particular the embodiments of the semiconductor device 400 having the curved terminal portions of the barrier base structure 228 may advantageously be combined with the curved connection portions Sc of the semiconductor device 200, since both features jointly avoid defective resist coverage during a lithography process for arranging the metal layer (e.g. copper) metal layer structure 108.

Various examples will be illustrated in the following:

Example 1 is a semiconductor device. The semiconductor device may include a semiconductor substrate including an active area, a metal layer structure over the active area, wherein the metal layer structure is configured to form an electrical contact, the metal layer structure including: a solder area, a buffer area, and a barrier area between the solder area and the buffer area, wherein, in the barrier area, the metal layer structure is arranged over a barrier base structure, and wherein the barrier base structure includes at least two segments extending along two different directions and a curved connecting segment connecting the two segments.

In Example 2, the subject-matter of Example 1 may optionally include that a radius of curvature of the curved connecting segment is in a range from 10 μm to 1 mm.

In Example 3, the subject-matter of Example 1 or 2 may optionally include that the solder area is configured to be contacted by a metal contact structure with a rounded corner, wherein the rounded corner is to be arranged adjacent to the curved connecting segment and has a predefined radius of curvature, and that a radius of curvature of the curved connecting segment is in a range from 50% to 200%, optionally 100%, of the predefined radius of curvature.

In Example 4, the subject-matter of any of Examples 1 to 3 may optionally include that the segments extend parallel to edges of the semiconductor substrate.

In Example 5, the subject-matter of any of Examples 1 to 4 may optionally include that the two different directions are orthogonal to each other.

In Example 6, the subject-matter of any of Examples 1 to 5 may optionally further include a further barrier area between the barrier area and the buffer area, wherein the further barrier area is formed to encircle the barrier area at least partly.

In Example 7, the subject-matter of Example 6 may optionally include that, in the further barrier area, the metal layer structure is arranged over a further barrier base structure, and that the further barrier base structure includes at least two segments extending along two different directions and a curved connecting segment connecting the two segments.

In Example 8, the subject-matter of Example 6 or 7 may optionally include that the further barrier area runs parallel to the barrier area.

In Example 9, the subject-matter of Example 6 or 7 may optionally include that a radius of curvature of the curved connecting segment of the further barrier base structure is larger or smaller than the radius of curvature of the curved connecting segment of the barrier base structure.

In Example 10, the subject-matter of any of Examples 1 to 9 may optionally include that the barrier base structure is a single barrier base layer or a barrier base layer stack including a plurality of barrier base layers.

In Example 11, the subject-matter of any of Examples 1 to 10 may optionally include that the barrier base structure includes or consists of a dielectric material.

In Example 12, the subject-matter of Example 11 may optionally include that the dielectric material of the barrier base structure includes or consists of at least one material of a group of dielectric materials, the group consisting of an imide, an oxide, and a nitride.

In Example 13, the subject-matter of any of Examples 1 to 10 may optionally include that the barrier base structure includes or consists of a metal.

In Example 14, the subject-matter of Example 13 may optionally include that the metal of the barrier base structure includes or consists of at least one material of a group of metals, the group consisting of aluminum, tungsten, copper, and alloys thereof.

In Example 15, the subject-matter of Example 13 or 14 may optionally include that the metal of the barrier base structure is the same as the metal of the metal layer structure.

In Example 16, the subject-matter of any of Examples 1 to 15 may optionally further include one or more additional segments and additional curved segments connecting the segments and the additional segments, wherein the curved segments and the additional curved segments have different radii.

In Example 17, the subject-matter of any of Examples 1 to 15 may optionally further include one or more additional segments and additional curved segments connecting the segments and the additional segments, wherein the curved segments and the additional curved segments have the same radii.

Example 18 is a semiconductor device. The semiconductor device may include a semiconductor substrate including an active area, a metal layer structure over the active area, wherein the metal layer structure is configured to form an electrical contact, the metal layer structure including: a solder area, a buffer area, a barrier area between the solder area and the buffer area, and an insulated metal structure extending from an edge region of the semiconductor device to the solder area, wherein, in the barrier area, the metal layer structure is arranged over a barrier base structure, and wherein the barrier base structure is formed as a contiguous structure that surrounds the solder area, except for gaps in the barrier base structure through which the insulated metal structure extends.

In Example 19, the subject-matter of Example 18 may optionally include that a distance between the insulated metal structure and the barrier base structure is in a range from about 5 μm to about 100 μm, for example about 30 μm.

In Example 20, the subject-matter of Example 18 or 19 may optionally include that a terminal portion of the barrier base structure adjacent to the insulated metal structure is rounded, curved or circular.

In Example 21, the subject-matter of any of Examples 18 to 20 may optionally include that the insulated metal structure traverses the solder area, extending from the edge region of the semiconductor device to an opposite edge region of the semiconductor device.

In Example 22, the subject-matter of any of Examples 18 to 21 may optionally include that the insulated metal structure is a gate finger or a sensor connection, for example for sensing current and/or voltage.

In Example 23, the subject-matter of any of Examples 1 to 22 may optionally further include a further barrier area between the barrier area and the buffer area.

In Example 24, the subject-matter of Example 23 may optionally include that, in the further barrier area, the metal layer structure is arranged over a further barrier base structure, and that the base structure and the further barrier base structure are connected by a curved connecting segment.

Example 25, the subject-matter of Example 23 may optionally include that the further barrier base structure includes or consists of a dielectric material or a metal.

In Example 26, the subject-matter of Example 25 may optionally include that the dielectric material of the further barrier base structure includes or consists of at least one material of a group of dielectric materials, the group consisting of an imide, an oxide, and a nitride.

In Example 27, the subject-matter of Example 25 may optionally include that the metal of the further barrier base structure includes or consists of at least one material of a group of metals, the group consisting of aluminum, tungsten, copper, and alloys thereof.

In Example 28, the subject-matter of any of Examples 25 to 27 may optionally include that the material of the barrier base structure and the material of the further barrier base structure are the same.

In Example 29, the subject-matter of any of Examples 1 to 28 may optionally include that the base structure and the further barrier base structure are connected by a curved connecting segment.

In Example 30, the subject-matter of any of Examples 1 to 29 may optionally include that the barrier base structure is free from sharp ends and free from sharp corners.

In Example 31, the subject-matter of any of Examples 1 to 30 may optionally further include a further electrical contact, wherein the barrier area is arranged between the solder area and the further electrical contact.

In Example 32, the subject-matter of any of Examples 1 to 31 may optionally further include a metal contact structure having a solder portion soldered to the solder area, wherein lateral dimensions of the solder area are configured to be larger than the lateral dimensions of the solder portion.

In Example 33, the subject-matter of Example 32 may optionally include that the metal contact structure is a metal clip.

In Example 34, the subject-matter of Example 32 or 33 may optionally include that the solder portion is arranged in the solder area.

In Example 35, the subject-matter of any of Examples 1 to 34 may optionally include that the semiconductor device is configured to have a current flow in a vertical direction through the semiconductor device.

In Example 36, the subject-matter of any of Examples 1 to 35 may optionally include that a height of the barrier base structure is in a range from 3 μm to 20 μm.

In Example 37, the subject-matter of any of Examples 1 to 36 may optionally include that the semiconductor device forms a discrete electronic component, a discrete electronic device, an integrated device or an integrated component.

In Example 38, the subject-matter of any of Examples 1 to 37 may optionally include that the semiconductor device forms one of a group of electronic components, the group consisting of: a diode, a thyristor, a MOSFET, a superjunction transistor, and an IGBT.

In Example 39, the subject-matter of any of Examples 1 to 38 may optionally include that the semiconductor device forms a power electronic component.

Example 40 is a method of forming a semiconductor device. The method may include forming an active area in a semiconductor substrate and forming a metal layer structure over the active area, wherein the metal layer structure is configured to form an electrical contact, the metal layer structure including a solder area, a buffer area, and a barrier area between the solder area and the buffer area, wherein, in the barrier area, the metal layer structure is arranged over a barrier base structure, and wherein the barrier base structure includes at least two segments extending along two different directions and a curved connecting segment connecting the two segments.

Example 41 is a method of forming a semiconductor device. The method may include forming an active area in a semiconductor substrate and forming a metal layer structure over the active area, wherein the metal layer structure is configured to form an electrical contact, the metal layer structure including a solder area, a buffer area, a barrier area between the solder area and the buffer area, and an insulated metal structure extending from an edge region of the semiconductor device to the solder area, wherein, in the barrier area, the metal layer structure is arranged over a barrier base structure, and wherein the barrier base structure is formed as a contiguous structure that surrounds the solder area, except for gaps in the barrier base structure through which the insulated metal structure extends.

In Example 42, the subject matter of any of Examples 1 to 17 may further optionally include an insulated metal structure extending from an edge region of the semiconductor device to the solder area, wherein the barrier base structure is formed as a contiguous structure that surrounds the solder area, except for gaps in the barrier base structure through which the insulated metal structure extends.

In Example 43, the subject matter of any of Examples 18 to 39 may optionally further include that the barrier base structure includes at least two segments extending along two different directions and a curved connecting segment connecting the two segments.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A semiconductor device, comprising:
a semiconductor substrate comprising an active area;
a metal layer structure over the active area, wherein the metal layer structure is configured to form an electrical contact, the metal layer structure comprising:
a solder area;
a buffer area; and
a barrier area between the solder area and the buffer area,
wherein, in the barrier area, the metal layer structure is arranged over a barrier base structure,
wherein the barrier base structure comprises at least two segments extending along two different directions, and a curved connecting segment connecting the at least two segments.

2. The semiconductor device of claim 1,
wherein a radius of curvature of the curved connecting segment is in a range from 10 μm to 1 mm.

3. The semiconductor device of claim 1,
wherein the solder area is configured to be contacted by a metal contact structure with a rounded corner, wherein the rounded corner is to be arranged adjacent to the curved connecting segment and has a predefined radius of curvature, and
wherein a radius of curvature of the curved connecting segment is in a range from 50% to 200% of the predefined radius of curvature.

4. The semiconductor device of claim 1,
wherein the at least two segments extend parallel to edges of the semiconductor substrate.

5. The semiconductor device of claim 1,
wherein the two different directions are orthogonal to each other.

6. The semiconductor device of claim 1, further comprising:
a further barrier area between the barrier area and the buffer area, wherein the further barrier area is formed to encircle the barrier area at least partly.

7. The semiconductor device of claim 6,
wherein, in the further barrier area, the metal layer structure is arranged over a further barrier base structure, and
wherein the further barrier base structure comprises at least two segments extending along two different directions and a curved connecting segment connecting the at least two segments.

8. The semiconductor device of claim 7,
wherein a radius of curvature of the curved connecting segment of the further barrier base structure is smaller or larger than the radius of curvature of the curved connecting segment of the barrier base structure.

9. The semiconductor device of claim 6,
wherein the further barrier area runs parallel to the barrier area.

10. The semiconductor device of claim 1, further comprising:
a further electrical contact,
wherein the barrier area is arranged between the solder area and the further electrical contact.

11. The semiconductor device of claim 1, further comprising:
a metal contact structure having a solder portion soldered to the solder area,
wherein lateral dimensions of the solder area are configured to be larger than the lateral dimensions of the solder portion.

12. The semiconductor device of claim 11,
wherein the metal contact structure is a metal clip.

13. The semiconductor device of claim 1,
wherein the semiconductor device is configured to have a current flow in a vertical direction through the semiconductor device.

14. A semiconductor device, comprising:
a semiconductor substrate comprising an active area;
a metal layer structure over the active area, wherein the metal layer structure is configured to form an electrical contact, the metal layer structure comprising:
a solder area;
a buffer area;
a barrier area between the solder area and the buffer area; and
an insulated metal structure extending from an edge region of the semiconductor device to the solder area,
wherein, in the barrier area, the metal layer structure is arranged over a barrier base structure,
wherein the barrier base structure is formed as a contiguous structure that surrounds the solder area, except for gaps in the barrier base structure through which the insulated metal structure extends.

15. The semiconductor device of claim 14,
wherein a distance between the insulated metal structure and the barrier base structure is in a range from about 5 μm to about 100 μm.

16. The semiconductor device of claim 14,
wherein a terminal portion of the barrier base structure adjacent to the insulated metal structure is rounded.

17. The semiconductor device of claim 14,
wherein the insulated metal structure traverses the solder area, extending from the edge region of the semiconductor device to an opposite edge region of the semiconductor device.

18. The semiconductor device of claim 14,
wherein the insulated metal structure is a gate finger or a connection to a sensor.

19. The semiconductor device of claim 14, further comprising:
a further barrier area between the barrier area and the buffer area.

20. The semiconductor device of claim 19,
wherein, in the further barrier area, the metal layer structure is arranged over a further barrier base structure, and
wherein the base structure and the further barrier base structure are connected by a curved connecting segment.

21. The semiconductor device of claim 14, further comprising:
a further electrical contact,
wherein the barrier area is arranged between the solder area and the further electrical contact.

22. The semiconductor device of claim 14, further comprising:
a metal contact structure having a solder portion soldered to the solder area,
wherein lateral dimensions of the solder area are configured to be larger than the lateral dimensions of the solder portion.

23. The semiconductor device of claim 22,
wherein the metal contact structure is a metal clip.

24. The semiconductor device of claim 14,
wherein the semiconductor device is configured to have a current flow in a vertical direction through the semiconductor device.
